(19) United States
(12) Patent Application Publication
(10) Pub. No.: US 2024/0387476 A1
(43) Pub. Date: Nov. 21, 2024

(54) METHOD FOR TRANSFERRING LEDS AND LIGHT-EMITTING BASE PLATE

(71) Applicant: SHENZHEN CHINA STAR OPTOELECTRONICS SEMICONDUCTOR DISPLAY TECHNOLOGY CO., LTD., Shenzhen, Guangdon (CN)

(72) Inventors: Bo SUN, Shenzhen, Guangdon (CN); Feng ZHENG, Shenzhen, Guangdon (CN); Quansheng LIU, Shenzhen, Guangdon (CN)

(21) Appl. No.: 17/596,680

(22) PCT Filed: Nov. 30, 2021
(86) PCT No.: PCT/CN2021/134271

§ 371 Date: Jul. 25, 2024

(30) Foreign Application Priority Data
Nov. 23, 2021 (CN) 2021111392642.7

(51) Int. Cl. H01L 25/075; H01L 33/00; H01L 33/62

(52) U.S. Cl. CPC H01L 25/0753; H01L 33/0093; H01L 33/62; H01L 2933/0066

(57) ABSTRACT

A method for transferring light-emitting diodes (LEDs) and a light-emitting base plate are disclosed. The method for transferring LEDs includes: providing a target base plate and a transfer base plate, wherein the target base plate includes a target substrate and a barrier layer, wherein a plurality of clamping grooves are formed by the barrier layer and the target substrate; and a plurality of LEDs are connected to a side of the transfer base plate; aligning the target base plate with the transfer base plate; and moving the transfer base plate in a preset direction, to cause the LEDs to be separated from the transfer base plate.

### FIELD OF INVENTION

The present disclosure relates to the field of display technologies, and specifically, to a method for transferring light-emitting diodes (LEDs) and a light-emitting base plate.

### BACKGROUND OF INVENTION

The mini light-emitting diode (mini-LED) and the micro light-emitting diode (micro-LED) are widely regarded as next-generation display technologies following the liquid crystal display. However, the mini-LED and the micro-LED currently encounter some technological difficulties such as an unstable driving circuit, difficult mass transfer, and a low transfer yield.

### SUMMARY OF INVENTION

### Technical Problem

In the mass transfer processes of LEDs, with regard to the laser transfer technology, using the existing mainstream 8K display as an example, since the display includes hundreds of millions of sub-pixels, but only about 10 million LEDs can be transferred per hour even using the most efficient infrared laser transfer technology, the laser transfer technology has a relatively low transfer rate. In addition, since the LEDs are irradiated by the high-energy laser during the laser transfer, there is a risk of performance degradation of the LEDs. The transfer technology using conventional die bonders and needle bonders cannot meet the requirements for mass transfer of LEDs due to the limited transfer precision and rate. In addition, the stamp transfer method has disadvantages such as high material costs for polydimethylsiloxane (PDMS) and high costs for wafer arrangement.

Therefore, it is of large significance to provide a novel feasible mass transfer solution for LEDs.

### Technical Solution

Embodiments of the present disclosure provide a novel method for transferring LEDs and a light-emitting base plate.

An embodiment of the present disclosure provides a method for transferring LEDs, including steps of:
providing a target base plate and a transfer base plate, wherein the target base plate includes a target substrate and a barrier layer disposed on a side of the target substrate, wherein a plurality of clamping grooves are formed by the barrier layer and the target substrate; and a plurality of LEDs are connected to a side of the transfer base plate;
aligning the target base plate with the transfer base plate, to cause the LEDs to be at least partially located in the clamping grooves; and
moving the transfer base plate in a preset direction, wherein the preset direction and a plane in which the target substrate is located are parallel or intersect non-orthogonally, to cause the LEDs to be separated from the transfer base plate.

Optionally, in some embodiments of the present disclosure, the mechanical strength of the barrier layer is greater than the bonding strength between the LEDs and the transfer base plate.

Optionally, in some embodiments of the present disclosure, in the step of aligning the target base plate with the transfer base plate, the LEDs are located in the clamping grooves by at least half the thickness of the LEDs in a direction perpendicular to the plane in which the target substrate is located.

Optionally, in some embodiments of the present disclosure, a distance between a surface of the barrier layer away from the target substrate and the target substrate ranges from 50 μm to 70 μm, and a distance between a surface of each of the LEDs away from the target substrate and the target substrate ranges from 80 μm to 100 μm.

Optionally, in some embodiments of the present disclosure, the transfer base plate is a growth substrate, support cantilevers are connected between the growth substrate and the LEDs, and the mechanical strength of the barrier layer is greater than an anchoring force between the LEDs and the support cantilevers; and
in the step of moving the transfer base plate in a preset direction, the LEDs are separated from the support cantilevers.

Optionally, in some embodiments of the present disclosure, the transfer base plate includes a blue film connected to the plurality of LEDs, wherein the mechanical strength of the barrier layer is greater than the adhesion between the LEDs and the blue film; and
in the step of moving the transfer base plate in a preset direction, the LEDs are separated from the blue film.

Optionally, in some embodiments of the present disclosure, the barrier layer is formed using an inkjet printing process, and the material of the barrier layer includes a polymer.

Optionally, in some embodiments of the present disclosure, the polymer includes polyimide, epoxy resin, or acrylic resin.

Optionally, in some embodiments of the present disclosure, the material of the barrier layer includes a light-shielding material.

Optionally, in some embodiments of the present disclosure, the target base plate further includes a plurality of pad sets disposed on the side of the target substrate, one of the pad sets is exposed from one of the clamping grooves, the thickness of the pad sets is less than the depth of the clamping grooves, conductive contacts are connected to sides of the LEDs away from the transfer base plate, and after the step of moving the transfer base plate in a preset direction, the method further includes:
soldering the conductive contacts to the corresponding pad sets.

Optionally, in some embodiments of the present disclosure, the LEDs are mini-LEDs or micro-LEDs.

An embodiment of the present disclosure further provides a method for transferring LEDs, including steps of:
providing a target base plate and a transfer base plate, wherein the target base plate includes a target substrate and a barrier layer disposed on a side of the target substrate, wherein a plurality of clamping grooves are formed by the barrier layer and the target substrate; and a plurality of LEDs are connected to a side of the transfer base plate, the mechanical strength of the barrier layer is greater than the bonding strength between the LEDs and the transfer base plate, and the material of the barrier layer includes a polymer;
aligning the target base plate with the transfer base plate, to cause the LEDs to be at least partially located in the clamping grooves; and
moving the transfer base plate in a preset direction, wherein the preset direction and a plane in which the target substrate is located are parallel or intersect non-orthogonally, to cause the LEDs to be separated from the transfer base plate.

Optionally, in some embodiments of the present disclosure, in the step of aligning the target base plate with the transfer base plate, the LEDs are located in the clamping grooves by at least half the thickness of the LEDs in a direction perpendicular to the plane in which the target substrate is located.

Optionally, in some embodiments of the present disclosure, a distance between a surface of the barrier layer away from the target substrate and the target substrate ranges from 50 μm to 70 μm, and a distance between a surface of each of the LEDs away from the target substrate and the target substrate ranges from 80 μm to 100 μm.

Optionally, in some embodiments of the present disclosure, the transfer base plate is a growth substrate, support cantilevers are connected between the growth substrate and the LEDs, and the mechanical strength of the barrier layer is greater than an anchoring force between the LEDs and the support cantilevers; and
in the step of moving the transfer base plate in a preset direction, the LEDs are separated from the support cantilevers.

Optionally, in some embodiments of the present disclosure, the transfer base plate includes a blue film connected to the plurality of LEDs, wherein the mechanical strength of the barrier layer is greater than the adhesion between the LEDs and the blue film; and
in the step of moving the transfer base plate in a preset direction, the LEDs are separated from the blue film.

Optionally, in some embodiments of the present disclosure, the barrier layer is formed using an inkjet printing process.

Optionally, in some embodiments of the present disclosure, the material of the barrier layer includes a light-shielding material.

Optionally, in some embodiments of the present disclosure, the target base plate further includes a plurality of pad sets disposed on the side of the target substrate, one of the pad sets is exposed from one of the clamping grooves, the thickness of the pad sets is less than the depth of the clamping grooves, conductive contacts are connected to sides of the LEDs away from the transfer base plate, and after the step of moving the transfer base plate in a preset direction, the method further includes:
soldering the conductive contacts to the corresponding pad sets.

An embodiment of the present disclosure provides a light-emitting base plate, including:
a target base plate, wherein the target base plate includes a target substrate, and a barrier layer and a plurality of pad sets that are disposed on a side of the target substrate, wherein a plurality of clamping grooves are formed by the barrier layer and the target substrate, and one of the pad sets is exposed from one of the clamping grooves, and the thickness of the pad sets is less than the depth of the clamping grooves; and
a plurality of light-emitting diodes (LEDs), wherein one of the LEDs is correspondingly disposed in one of the clamping grooves and is connected to the pad set, wherein a distance between a surface of each of the LEDs away from the target substrate and the target substrate is greater than a distance between a surface of the barrier layer away from the target substrate and the target substrate.

### Beneficial Effects

In the method for transferring LEDs provided in the present disclosure, a barrier layer is disposed in a target base plate, and clamping grooves are formed between the barrier layer and the target substrate. Therefore, during transfer of the LEDs, when the LEDs are disposed in the clamping grooves, moving directions of the LEDs are limited using the blocking effect of the barrier layer, so that when the transfer base plate is moved in a direction that is parallel to or intersects non-orthogonally with a plane in which the target substrate is located, the LEDs can be directly separated from the transfer base plate, to complete the transfer of the LEDs.

### BRIEF DESCRIPTION OF DRAWINGS

To describe the technical solutions in the embodiments of the present disclosure more clearly, the following briefly describes accompanying drawings required for describing the embodiments. The accompanying drawings in the following descriptions show merely some embodiments of the present disclosure, and a person skilled in the art may still derive other accompanying drawings according to such accompanying drawings without creative efforts.

FIG. 1 is a schematic flowchart of a method for transferring LEDs according to the present disclosure.

FIG. 2 is a schematic flowchart of a method for transferring LEDs according to Example 1 of the present disclosure.

FIGS. 3A to 3D are schematic diagrams of structures that are sequentially obtained through steps of the method for transferring LEDs shown in FIG. 2.

FIG. 4 is a schematic top view of performing an alignment operation on a transfer base plate and a target base plate according to the method for transferring LEDs shown in FIG. 2.

FIG. 5 is a schematic flowchart of a method for transferring LEDs according to Example 2 of the present disclosure.

FIGS. 6A to 6J are schematic diagrams of structures that are sequentially obtained through steps of the method for transferring LEDs shown in FIG. 5.

FIG. 7 is a schematic flowchart of a method for transferring LEDs according to Example 3 of the present disclosure.

FIGS. 8A to 8D are schematic diagrams of structures that are sequentially obtained through steps of the method for transferring LEDs shown in FIG. 7.

FIG. 9 is a schematic diagram of a structure of a light-emitting base plate according to the present disclosure.

FIG. 10 is a schematic diagram of a structure of a display panel according to the present disclosure.

### DETAILED DESCRIPTION OF PREFERRED EMBODIMENTS

The technical solutions in the embodiments of the present disclosure are clearly and completely described below with reference to the accompanying drawings in the embodiments of the present disclosure. Apparently, the described embodiments are merely some rather than all of the embodiments of the present disclosure. All other embodiments obtained by a person skilled in the art based on the embodiments of the present disclosure without creative efforts shall fall within the protection scope of the present disclosure. In addition, it should be understood that specific implementations described herein are merely used for describing and illustrating the present disclosure, but are not intended to limit the present disclosure. In the present disclosure, unless otherwise stated, the directional terms used, in a detailed description, refer to directions in drawing surfaces of the corresponding accompanying drawings. For example, “above” and “below” generally refer to an upper position and a lower position in actual use or a working state of a device. Moreover, “inside” and “outside” are relative to the contour of the device.

The present disclosure provides a method for transferring LEDs and a light-emitting base plate. Detailed descriptions are separately provided below. It should be noted that, the description order of the following embodiments is not construed as a limitation to preference orders of the embodiments.

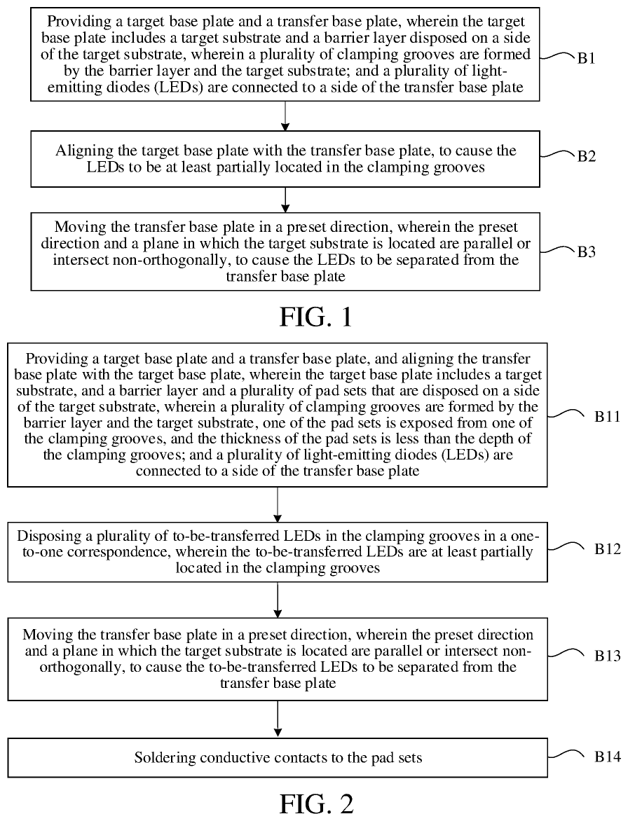

Referring to FIG. 1, the present disclosure provides a method for transferring LEDs. The method includes steps of:
B1: Providing a target base plate and a transfer base plate, wherein the target base plate includes a target substrate and a barrier layer disposed on a side of the target substrate, wherein a plurality of clamping grooves are formed by the barrier layer and the target substrate; and a plurality of LEDs are connected to a side of the transfer base plate.
B2: Aligning the target base plate with the transfer base plate, to cause the LEDs to be at least partially located in the clamping grooves.
B3: Moving the transfer base plate in a preset direction, wherein the preset direction and a plane in which the target substrate is located are parallel or intersect non-orthogonally, to cause the LEDs to be separated from the transfer base plate.

In the method for transferring LEDs provided in the present disclosure, a barrier layer is disposed in a target base plate, and clamping grooves are formed between the barrier layer and the target substrate. Therefore, during transfer of the LEDs, when the LEDs are disposed in the clamping grooves, moving directions of the LEDs are limited using the blocking effect of the barrier layer, so that when the transfer base plate is moved in a direction that is parallel to or intersects non-orthogonally with a plane in which the target substrate is located, the LEDs can be directly separated from the transfer base plate, to complete the transfer of the LEDs.

The method for transferring LEDs provided in the present disclosure is described in detail below using specific embodiments.

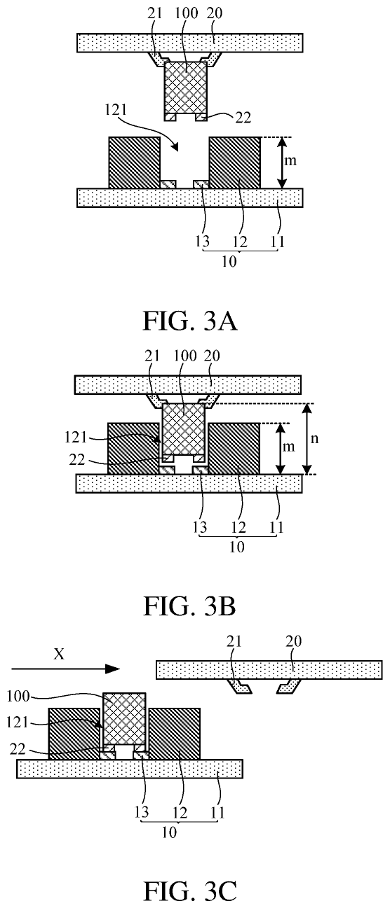

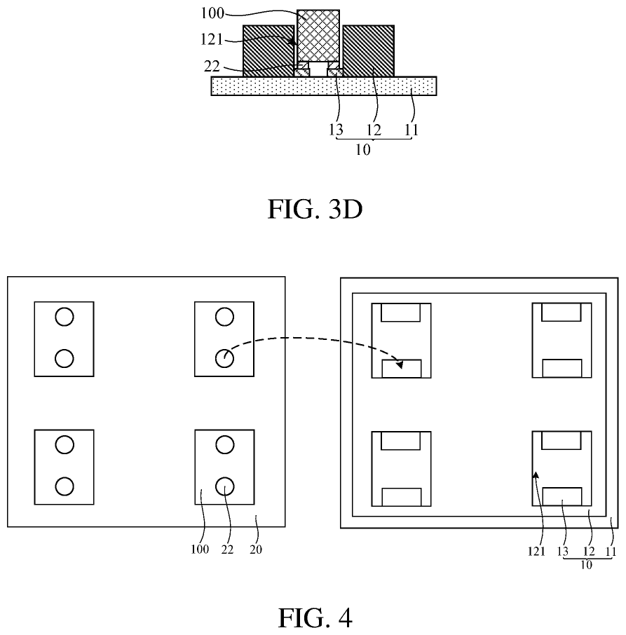

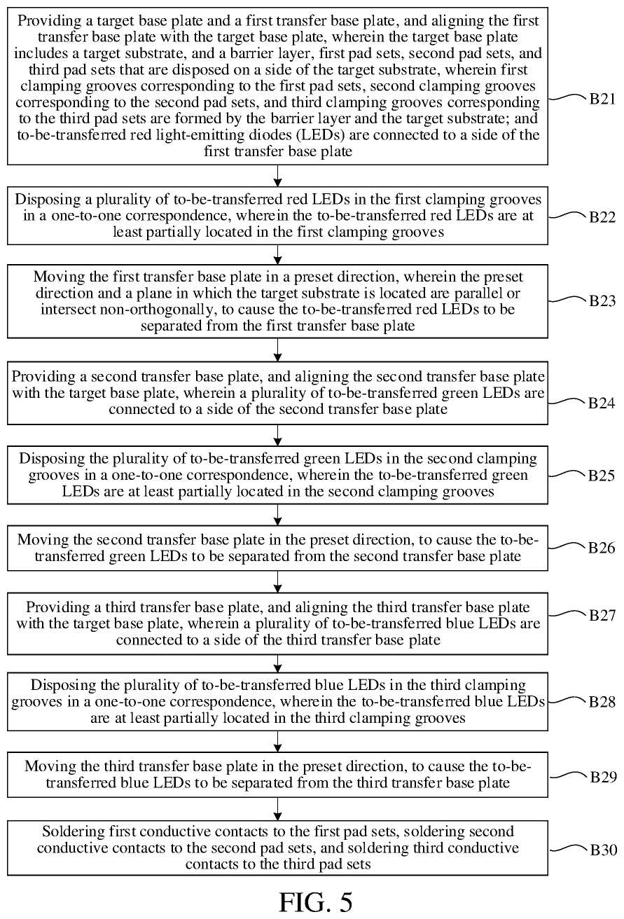

Referring to FIG. 2, FIGS. 3A to 3D, and FIG. 4 together, Example 1 of the present disclosure provides a method for transferring LEDs. The method includes steps of:
B11: Providing a target base plate 10 and a transfer base plate 20, and aligning the transfer base plate 20 with the target base plate 10, wherein the target base plate 10 includes a target substrate 11, and a barrier layer 12 and a plurality of pad sets 13 that are disposed on a side of the target substrate 11, wherein a plurality of clamping grooves 121 are formed by the barrier layer 12 and the target substrate 11, one of the pad sets 13 is exposed from one of the clamping grooves 121, and the thickness of the pad sets 13 is less than the depth of the clamping grooves 121; and a plurality of LEDs 100 are connected to a side of the transfer base plate 20, as shown in FIG. 3A.

The target substrate 11 may be a driving base plate. The driving base plate includes thin film transistors (not shown in the figure) configured to drive the LEDs 100 to emit light. The related technologies all belong to the prior art, which are not described herein in detail.

The plurality of pad sets 13 are formed in a process for manufacturing the target substrate 11. Each of the pad sets 13 includes a positive-polarity pad and a negative-polarity pad (not marked in the figure). The positive-polarity pad is configured to connect to an anode of the LED 100, and the negative-polarity pad is configured to connect to a cathode of the LED 100.

In the present embodiment, a thickness m of the barrier layer 12 ranges from 50 μm to 70 μm. In a detailed description, the thickness m of the barrier layer 12 refers to a distance between a surface of the barrier layer 12 away from the target substrate 11 and the target substrate 11. In some specific implementations, the thickness m of the barrier layer 12 may be 50 μm, 52 μm, 55 μm, 57 μm, 58 μm, 60 μm, 62 μm, 65 μm, 68 μm, 70 μm, or the like. The depth of the clamping grooves 121 is equal to the thickness m of the barrier layer 12.

The material of the barrier layer 12 may include a polymer. The polymer has relatively good mechanical strength. Therefore, it can be ensured that the barrier layer 12 has relatively high mechanical strength. In addition, the polymer has good toughness, and therefore, helps improve the toughness of the barrier layer 12 and prevent the barrier layer 12 from being damaged during subsequent transfer of the LEDs 100. In a detailed description, the polymer may include polyimide, epoxy resin, acrylic resin, or the like.

In some embodiments, the material of the barrier layer 12 may further include inorganic materials of good mechanical strength such as silicon nitride, silicon oxide, silicon oxynitride, or the like, which is not described herein in detail.

Further, in the present embodiment, the material of the barrier layer 12 includes a light-shielding material. The light-shielding material may be a black matrix (BM), or may be another material with a light-shielding effect and good mechanical strength. Such a configuration enables the barrier layer 12 to be used as a light-shielding layer between sub-pixels after the transfer of the LEDs 100, thereby omitting the configuration of a light-shielding film layer between adjacent sub-pixels, simplifying the manufacturing process, and saving process costs. In some embodiments, when the LEDs 100 are applied to transparent display, the material of the barrier layer 12 may be a transparent material, which is not described herein in detail again.

In the present embodiment, the barrier layer 12 is manufactured after pad sets 13 are formed on the target substrate 11. In a detailed description, the barrier layer 12 may be formed using an inkjet printing process or a photolithography process. The barrier layer 12 covers a relatively large area on the target substrate 11. Therefore, the inkjet printing process is preferably adopted to manufacture the barrier layer 12, thereby simplifying the process.

The transfer base plate 20 may be a growth substrate. The growth substrate may be a sapphire substrate, a gallium arsenide substrate, a silicon-based substrate, or the like. The LEDs 100 may be mini-LEDs or micro-LEDs. In the present embodiment, conductive contacts 22 are connected to sides of the LEDs 100 away from the transfer base plate 20. The conductive contacts 22 are configured to bind and bond to the pad sets 13 on the target base plate 10. In a detailed description, the material of conductive contacts 22 may include one or more of metals having a low melting point such as tin, indium, lead, or bismuth.

In the present embodiment, the mechanical strength of the barrier layer 12 is greater than the bonding strength between the LEDs 100 and the transfer base plate 20. The bonding strength may be an intermolecular force, such as an anchoring force, or adhesion.

As shown in FIG. 3A, support cantilevers 21 may be connected between the growth substrate and the LEDs 100, and the support cantilevers 21 and the growth substrate are connected by the anchoring force. The support cantilevers 21 provide a supporting effect for the LEDs 100, to help separate the LEDs 100 from the growth substrate. In the present embodiment, the mechanical strength of the barrier layer 12 is greater than the anchoring force between the LEDs 100 and the support cantilevers 21.

It should be noted that, the support cantilevers 21 are obtained by etching the LEDs 100 after a process for manufacturing the LEDs 100. In the present disclosure, the structure of the support cantilevers 21 is merely an example and is used for representing a connection relationship between the support cantilevers 21 and the LEDs 100, but should not be understood as a limitation to the present disclosure. In addition, for a related manufacturing process and the structure of the support cantilevers 21, reference may be made to the prior art, so details are not described herein again.

Referring to FIG. 3A and FIG. 4, when the transfer base plate 20 is aligned with the target base plate 10, the conductive contacts 22 on the transfer base plate 20 are made to be in a one-to-one correspondence with the pad sets 13 in the target base plate 10, to improve the alignment accuracy.
B12: Disposing the plurality of LEDs 100 in the clamping grooves 121 in a one-to-one correspondence, wherein the LEDs 100 are at least partially located in the clamping grooves 121, as shown in FIG. 3B.

In the present embodiment, the LEDs 100 are located in the clamping grooves 121 by at least half the thickness of the LEDs 100 in a direction perpendicular to a plane in which the target substrate 11 is located. Arms of the support cantilevers 21 on the transfer base plate 20 are relatively large. To prevent the LEDs 100 from damaging the barrier layer 12 during subsequent transfer, centers of gravity of the LEDs 100 are located at lower parts of the clamping grooves 121 when the LEDs 100 are extended into the clamping grooves 121 by half the thickness of the LEDs 100, to reduce the arms of the support cantilevers 21. Preferably, the LEDs 100 cannot completely extend into the clamping grooves 121 to prevent the barrier layer 12 from coming into contact with the transfer base plate 20 and being damaged.

In some embodiments, when the mechanical strength of the barrier layer 12 is large enough, the LEDs 100 may alternatively be extended into the clamping grooves 121 by less than half the thickness of the LEDs 100, which is not described herein in detail again.

Because the depth of the clamping grooves 121 ranges from 50 μm to 70 μm, in the present embodiment, a distance n between a surface of each of the LEDs 100 away from the target substrate 11 and the target substrate 11 may range from 80 μm to 100 μm. In some specific implementations, the distance n between a surface of each of the LEDs 100 away from the target substrate 11 and the target substrate 11 may be 80 μm, 82 μm, 85 μm, 88 μm, 90 μm, 92 μm, 95 μm, 98 μm, or 100 μm.

Further, a specific distance is reserved between the conductive contacts 22 and the pad sets 13 after the LEDs 100 are extended into the clamping grooves 121, to ensure that the conductive contacts 22 are not in contact with the pad sets 13, thereby preventing the conductive contacts 22 from scratching the pad sets 13.
B13: Moving the transfer base plate 20 in a preset direction X, wherein the preset direction X and a plane in which the target substrate 11 is located are parallel or intersect non-orthogonally, to cause the LEDs 100 to be separated from the transfer base plate 20, as shown in FIG. 3C.

The anchoring force between the LEDs 100 and the support cantilevers 21 is less than the mechanical strength of the barrier layer 12. Therefore, during the movement of the transfer base plate 20, the LEDs 100 are separated from the support cantilevers 21 under the mechanical action of the barrier layer 12, thereby falling onto the pad sets 13 in the clamping grooves 121. Transfer of the LEDs 100 under the action of mechanical force is achieved using the above transfer method. Therefore, the difficulty in transferring of the LEDs 100 is greatly reduced. In addition, no additional instrument or device is required during the transfer. Therefore, process costs can be greatly reduced.

In the present embodiment, the preset direction X is parallel to the plane in which the target substrate 11 is located. The LEDs 100 are connected to the conductive contacts 22. The above configuration can prevent the LEDs 100 from being misaligned during the movement of the transfer base plate 20 and affecting the alignment between the conductive contacts 22 and the pad sets 13, thereby further improving the alignment accuracy of the LEDs 100.

It should be noted that, that “intersect non-orthogonally” refers to a case that an angle formed between the preset direction X and the plane in which the target substrate 11 is located is an acute angle or an obtuse angle, which is not described herein in detail.
B14: Soldering the conductive contacts 22 to the corresponding pad sets 13, as shown in FIG. 3D.

The conductive contacts 22 are melted in a manner of reflow soldering, so that the conductive contacts 22 are bonded to the pad sets 13, thereby completing the transfer of the LEDs 100.

In the method for transferring LEDs 100 provided in Example 1 of the present disclosure, a barrier layer 12 is disposed in a target base plate 10, clamping grooves 121 are formed between the barrier layer 12 and a target substrate 11. Therefore, during transfer of the LEDs 100, when the LEDs 100 are disposed in the clamping grooves 121, on the one hand, moving directions of the LEDs 100 may be limited using the blocking effect of the barrier layer 12; and on the other hand, because the mechanical strength of the barrier layer 12 is greater than the bonding strength between the LEDs 100 and the transfer base plate 20, when the transfer base plate 20 is moved in a direction parallel to a plane in which the target substrate 11 is located, the LEDs 100 can be easily separated from the transfer base plate 20, to complete the transfer of the LEDs 100. In addition, the method for transferring LEDs 100 provided in the present disclosure is performed under the action of a mechanical force. Therefore, the difficulty in transferring of the LEDs 100 is greatly reduced.

Further, the method for transferring LEDs 100 provided in the present disclosure is performed without adopting the laser irradiation technology, so that the risk of performance degradation of the LEDs 100 caused by laser irradiation can be reduced. Moreover, the LEDs 100 can be separated from the transfer base plate 20 at a time, so that requirements for mass transfer of the LEDs 100 can be met, and the transfer rate can be greatly improved. In addition, no additional instrument or device is required during the transfer. Therefore, process costs can be greatly reduced.

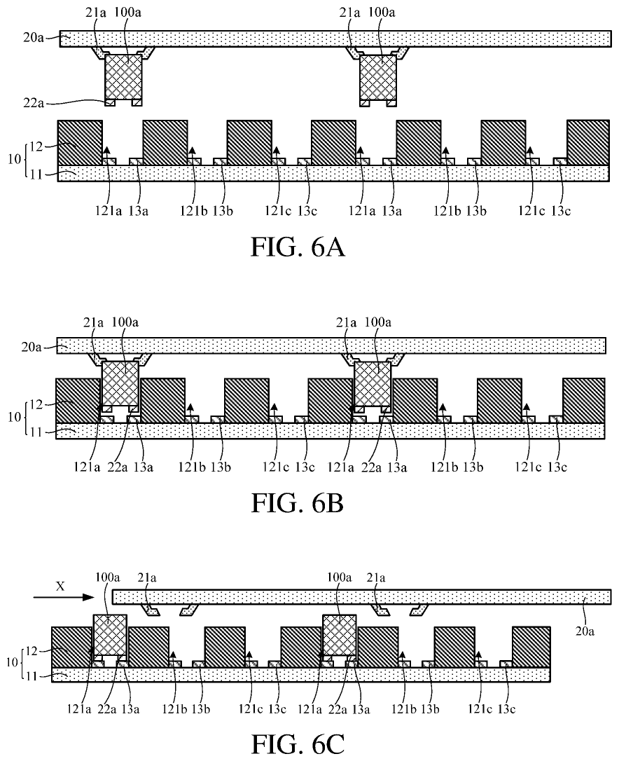

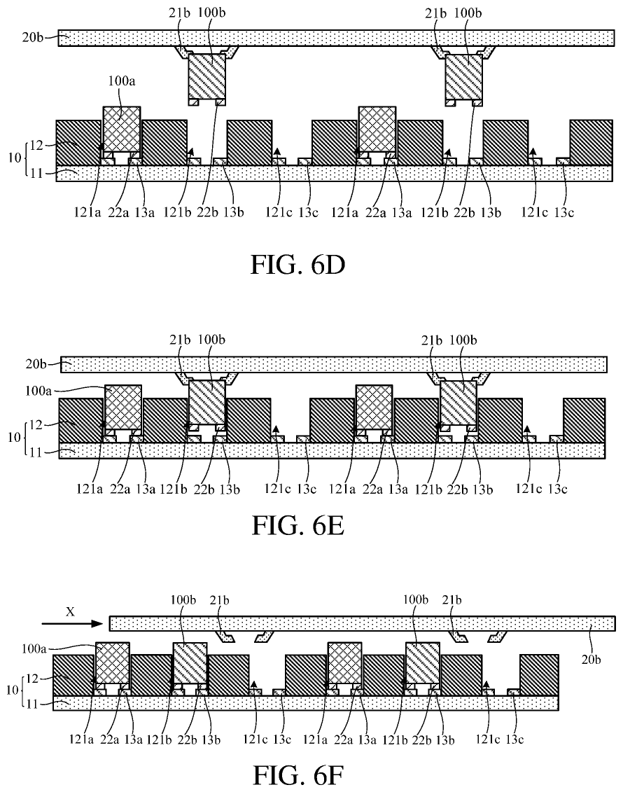

Referring to FIG. 5 and FIGS. 6A to 6J together, Example 2 of the present disclosure further provides a method for transferring LEDs, including steps of:
B21: Providing a target base plate 10 and a first transfer base plate 20a, and aligning the first transfer base plate 20a with the target base plate 10, wherein the target base plate 10 includes a target substrate 11, and a barrier layer 12, first pad sets 13a, second pad sets 13b, and third pad sets 13c that are disposed on a side of the target substrate 11, wherein first clamping grooves 121a corresponding to the first pad sets 13a, second clamping grooves 121b corresponding to the second pad sets 13b, and third clamping grooves 121c corresponding to the third pad sets 13c are formed by the barrier layer 12 and the target substrate 11; and a plurality of red LEDs 100a are connected to a side of the first transfer base plate 20a, as shown in FIG. 6A.

The target substrate 11 may be a driving base plate. The driving base plate includes thin film transistors (not shown in the figure) configured to drive the LEDs to emit light. The related technologies all belong to the prior art, which are not described herein in detail.

One of the first pad sets 13a is exposed from one of the first clamping grooves 121a. The thickness of the first pad sets 13a is less than the depth of the first clamping grooves 121a. One of the second pad sets 13b is exposed from one of the second clamping grooves 121b. The thickness of the second pad sets 13b is less than the depth of the second clamping grooves 121b. One of the third clamping grooves 121c is exposed from one of the third pad sets 13c. The thickness of the third pad sets 13c is less than the depth of the third clamping grooves 121c.

The first pad sets 13a, the second pad sets 13b, and the third pad sets 13c are all formed in a process for manufacturing the target substrate 11. Each of the first pad sets 13a, each of the second pad sets 13b, and each of the third pad sets 13c each include a positive-polarity pad and a negative-polarity pad (not marked in the figure). The positive-polarity pad is configured to connect to an anode of the LED, and the negative-polarity pad is configured to connect to a cathode of the LED.

In the present embodiment, the thickness of the barrier layer 12 ranges from 50 μm to 70 μm. In a detailed description, the thickness m of the barrier layer 12 refers to a distance between a surface of the barrier layer 12 away from the target substrate 11 and the target substrate 11. In some specific implementations, the thickness of the barrier layer 12 may be 50 μm, 52 μm, 55 μm, 57 μm, 58 μm, 60 μm, 62 μm, 65 μm, 68 μm, 70 μm, or the like. The depths of the first clamping grooves 121a, the second clamping grooves 121b, and the third clamping grooves 121c are all equal to the thickness of the barrier layer 12.

The barrier layer 12 is manufactured after the first pad sets 13a, the second pad sets 13b, and the third pad sets 13c are formed on the target substrate 11. In a detailed description, the barrier layer 12 may be formed using an inkjet printing process or a photolithography process. The barrier layer 12 covers a relatively large area on the target substrate 11. Therefore, the inkjet printing process is preferably adopted to manufacture the barrier layer 12, thereby simplifying the process. It should be noted that, for the material of the barrier layer 12, reference may be made to the descriptions of Example 1, so details are not described herein again.

The first transfer base plate 20a may be a gallium arsenide substrate. The red LEDs 100a may be mini-LEDs or micro-LEDs. First conductive contacts 22a are connected to sides of the red LEDs 100a away from the first transfer base plate 20a. The first conductive contacts 22a are configured to bind and bond to the first pad sets 13a on the target base plate 10. In a detailed description, the material of the first conductive contacts 22a may include one or more of metals having a low melting point such as tin, indium, lead, or bismuth.

In the present embodiment, first support cantilevers 21a are connected between the first transfer base plate 20a and the red LEDs 100a. The first support cantilevers 21a and the first transfer base plate 20a are connected by the anchoring force. The first support cantilevers 21a provide a supporting effect for the red LEDs 100a, to help separate the red LEDs 100a from the first transfer base plate 20a. In the present embodiment, the mechanical strength of the barrier layer 12 is greater than the anchoring force between the red LEDs 100a and the first support cantilevers 21a

It should be noted that, the first support cantilevers 21a are obtained by etching the red LEDs 100a after a process for manufacturing the red LEDs 100a. In the present disclosure, the structure of the first support cantilevers 21a is merely an example and is used for representing a connection relationship between the first support cantilevers 21a and the red LEDs 100a, but should not be understood as a limitation to the present disclosure. In addition, for a related manufacturing process and the structure of the first support cantilevers 21a, reference may be made to the prior art, so details are not described herein again.

Further, when the first transfer base plate 20a is aligned with the target base plate 10, the first conductive contacts 22a on the first transfer base plate 20a are made to be in a one-to-one correspondence with the first pad sets 13a in the target base plate 10, to improve the alignment accuracy.
B22: Disposing the plurality of red LEDs 100a in the first clamping grooves 121a in a one-to-one correspondence, wherein the red LEDs 100a are at least partially located in the first clamping grooves 121a, as shown in FIG. 6B.

In the present embodiment, the red LEDs 100a are located in the first clamping grooves 121a by at least half the thickness of the red LEDs 100a in a direction perpendicular to a plane in which the target substrate 11 is located. Arms of the first support cantilevers 21a on the first transfer base plate 20a are relatively large. To prevent the red LEDs 100a from damaging the barrier layer 12 during subsequent transfer, centers of gravity of the red LEDs 100a are located at lower parts of the first clamping grooves 121a when the red LEDs 100a are extended into the first clamping grooves 121a by half the thickness of the red LEDs 100a, to reduce the arms of the first support cantilevers 21a. Preferably, the red LEDs 100a cannot completely extend into the first clamping grooves 121a to prevent the barrier layer 12 from coming into contact with the first transfer base plate 20a and being damaged.

In some embodiments, when the mechanical strength of the barrier layer 12 is large enough, the red LEDs 100a may alternatively be extended into the first clamping grooves 121a by less than half the thickness of the red LEDs 100a, which is not described herein in detail again.

Because the depth of the second clamping grooves 121b ranges from 50 μm to 70 μm, in the present embodiment, a distance between a surface of each of the green LEDs 100b away from the target substrate 11 and the target substrate 11 may range from 80 μm to 100 μm. In some specific implementations, the distance n between a surface of each of the red LEDs 100a away from the target substrate 11 and the target substrate 11 may be 80 μm, 82 μm, 85 μm, 88 μm, 90 μm, 92 μm, 95 μm, 98 μm, or 100 μm.

Further, a specific distance is reserved between the first conductive contacts 22a and the first pad sets 13a after the red LEDs 100a are extended into the first clamping grooves 121a, to ensure that the first conductive contacts 22a are not in contact with the first pad sets 13a, thereby preventing the first conductive contacts 22a from scratching the first pad sets 13a.
B23: Moving the first transfer base plate 20a in a preset direction X, wherein the preset direction X and a plane in which the target substrate 11 is located are parallel or intersect non-orthogonally, to cause the red LEDs 100a to be separated from the first transfer base plate 20a, as shown in FIG. 6C.

The anchoring force between the red LEDs 100a and the first support cantilevers 21a is less than the mechanical strength of the barrier layer 12. Therefore, during the movement of the first transfer base plate 20a, the red LEDs 100a are separated from the first support cantilevers 21a under the mechanical action of the barrier layer 12, thereby falling onto the first pad sets 13a in the first clamping grooves 121a. Transfer of the red LEDs 100a under the action of mechanical force is achieved using the above transfer method. Therefore, the difficulty in transferring of the red LEDs 100a is greatly reduced. In addition, no additional instrument or device is required during the transfer. Therefore, process costs can be greatly reduced.

In the present embodiment, the preset direction X is parallel to the plane in which the target substrate 11 is located. The red LEDs 100a are connected to the first conductive contacts 22a. The above configuration can prevent the red LEDs 100a from being misaligned during the movement of the first transfer base plate 20a and affecting the alignment between the first conductive contacts 22a and the first pad sets 13a, thereby further improving the alignment accuracy of the red LEDs 100a.

It should be noted that, that “intersect non-orthogonally” refers to a case that an angle formed between the preset direction X and the plane in which the target substrate 11 is located is an acute angle or an obtuse angle, which is not described herein in detail.
B24: Providing a second transfer base plate 20b, and aligning the second transfer base plate 20b with the target base plate 10, wherein a plurality of green LEDs 100b are connected to a side of the second transfer base plate 20b, as shown in FIG. 6D.

The second transfer base plate 20b may be a sapphire substrate. The green LEDs 100b may be mini-LEDs or micro-LEDs. Second conductive contacts 22b are connected to sides of the green LEDs 100b away from the second transfer base plate 20b. The second conductive contacts 22b are configured to bind and bond to the second pad sets 13b on the target base plate 10. In a detailed description, the material of the second conductive contacts 22b may include one or more of metals having a low melting point such as tin, indium, lead, or bismuth.

In the present embodiment, second support cantilevers 21b are connected between the second transfer base plate 20b and the green LEDs 100b. The second support cantilevers 21b and the second transfer base plate 20b are connected by the anchoring force. The second support cantilevers 21b provide a supporting effect for the green LEDs 100b, to help separate the green LEDs 100b from the second transfer base plate 20b. In the present embodiment, the mechanical strength of the barrier layer 12 is greater than the anchoring force between the green LEDs 100b and the second support cantilevers 21b.

It should be noted that, the second support cantilevers 21b are obtained by etching the green LEDs 100b after a process for manufacturing the green LEDs 100b. In the present disclosure, the structure of the second support cantilevers 21b is merely an example and is used for representing a connection relationship between the second support cantilevers 21b and the green LEDs 100b, but should not be understood as a limitation to the present disclosure. In addition, for a related manufacturing process and the structure of the second support cantilevers 21b, reference may be made to the prior art, so details are not described herein again.

Further, when the second transfer base plate 20b is aligned with the target base plate 10, the second conductive contacts 22b on the second transfer base plate 20b are made to be in a one-to-one correspondence with the second pad sets 13b in the target base plate 10, to improve the alignment accuracy.
B25: Disposing the plurality of green LEDs 100b in the second clamping grooves 121b in a one-to-one correspondence, wherein the green LEDs 100b are at least partially located in the second clamping grooves 121b, as shown in FIG. 6E.

In the present embodiment, the green LEDs 100b are located in the second clamping grooves 121b by at least half the thickness of the green LEDs 100b in a direction perpendicular to a plane in which the target substrate 11 is located. Arms of the second support cantilevers 21b on the second transfer base plate 20b are relatively large. To prevent the green LEDs 100b from damaging the barrier layer 12 during subsequent transfer, centers of gravity of the green LEDs 100b are located at lower parts of the second clamping grooves 121b when the green LEDs 100b are extended into the second clamping grooves 121b by half the thickness of the green LEDs 100b, to reduce the arms of the second support cantilevers 21b. Preferably, the green LEDs 100b cannot completely extend into the second clamping grooves 121b to prevent the barrier layer 12 from coming into contact with the second transfer base plate 20b and being damaged.

In some embodiments, when the mechanical strength of the barrier layer 12 is large enough, the green LEDs 100b may alternatively be extended into the second clamping grooves 121b by less than half the thickness of the green LEDs 100b, which is not described herein in detail again.

Because the depth of the first clamping grooves 121a ranges from 50 μm to 70 μm, in the present embodiment, a distance between a surface of each of the red LEDs 100a away from the target substrate 11 and the target substrate 11 may range from 80 μm to 100 μm. In some specific implementations, the distance between a surface of each of the green LEDs 100b away from the target substrate 11 and the target substrate 11 may be 80 μm, 82 μm, 85 μm, 88 μm, 90 μm, 92 μm, 95 μm, 98 μm, or 100 μm.

Further, a specific distance is reserved between the second conductive contacts 22b and the second pad sets 13b after the green LEDs 100b are extended into the second clamping grooves 121b, to ensure that the second conductive contacts 22b are not in contact with the second pad sets 13b, thereby preventing the second conductive contacts 22b from scratching the second pad sets 13b.
B26: Moving the second transfer base plate 20b in a preset direction X, to cause the green LEDs 100b to be separated from the second transfer base plate 20b, as shown in FIG. 6F.

The anchoring force between the green LEDs 100b and the second support cantilevers 21b is less than the mechanical strength of the barrier layer 12. Therefore, during the movement of the second transfer base plate 20b, the green LEDs 100b are separated from the second support cantilevers 21b under the mechanical action of the barrier layer 12, thereby falling onto the second pad sets 13b in the second clamping grooves 121b. Transfer of the green LEDs 100b under the action of mechanical force is achieved using the above transfer method. Therefore, the difficulty in transferring of the green LEDs 100b is greatly reduced. In addition, no additional instrument or device is required during the transfer. Therefore, process costs can be greatly reduced.
B27: Providing a third transfer base plate 20c, and aligning the third transfer base plate 20c with the target base plate 10, wherein a plurality of blue LEDs 100c are connected to a side of the third transfer base plate 20c, as shown in FIG. 6G.

The third transfer base plate 20c may be a sapphire substrate. The blue LEDs 100c may be mini-LEDs or micro-LEDs. Third conductive contacts 22c are connected to sides of the blue LEDs 100c away from the third transfer base plate 20c. The third conductive contacts 22c are configured to bind and bond to the third pad sets 13c on the target base plate 10. In a detailed description, the material of third conductive contacts 22c may include one or more of metals having a low melting point such as tin, indium, lead, or bismuth.

In the present embodiment, third support cantilevers 21c are connected between the third transfer base plate 20c and the blue LEDs 100c. The third support cantilevers 21c and the third transfer base plate 20c are connected by the anchoring force. The third support cantilevers 21c provide a supporting effect for the blue LEDs 100c, to help separate the blue LEDs 100c from the third transfer base plate 20c. In the present embodiment, the mechanical strength of the barrier layer 12 is greater than the anchoring force between the blue LEDs 100c and the third support cantilevers 21c.

It should be noted that, the third support cantilevers 21c are obtained by etching the blue LEDs 100c after a process for manufacturing the blue LEDs 100c. In the present disclosure, the structure of the third support cantilevers 21c is merely an example and is used for representing a connection relationship between the third support cantilevers 21c and the blue LEDs 100c, but should not be understood as a limitation to the present disclosure. In addition, for a related manufacturing process and the structure of the third support cantilevers 21c, reference may be made to the prior art, so details are not described herein again.

Further, when the third transfer base plate 20c is aligned with the target base plate 10, the third conductive contacts 22c on the third transfer base plate 20c are made to be in a one-to-one correspondence with the third pad sets 13c in the target base plate 10, to improve the alignment accuracy.
B28: Disposing the plurality of blue LEDs 100c in the third clamping grooves 121c in a one-to-one correspondence, wherein the blue LEDs 100c are at least partially located in the third clamping grooves 121c, as shown in FIG. 6H.

In the present embodiment, the blue LEDs 100c are located in the third clamping grooves 121c by at least half the thickness of the blue LEDs 100c in a direction perpendicular to a plane in which the target substrate 11 is located. Arms of the third support cantilevers 21c on the third transfer base plate 20c are relatively large. To prevent the blue LEDs 100c from damaging the barrier layer 12 during subsequent transfer, centers of gravity of the blue LEDs 100c are located at lower parts of the third clamping grooves 121c when at least one half of the thickness of each of the blue LEDs 100c are extended into the third clamping grooves 121c by half the thickness of the blue LEDs 100c, to reduce the arms of the third support cantilevers 21c. Preferably, the blue LEDs 100c cannot completely extend into the third clamping grooves 121c to prevent the barrier layer 12 from coming into contact with the third transfer base plate 20c and being damaged.

In some embodiments, when the mechanical strength of the barrier layer 12 is large enough, the blue LEDs 100c may alternatively be extended into the third clamping grooves 121c by less than half the thickness of the blue LEDs 100c, which is not described herein in detail again.

Because the depth of the third clamping grooves 121c ranges from 50 μm to 70 μm, in the present embodiment, a distance between a surface of each of the blue LEDs 100c away from the target substrate 11 and the target substrate 11 may range from 80 μm to 100 μm. In some specific implementations, the distance between a surface of each of the blue LEDs 100c away from the target substrate 11 and the target substrate 11 may be 80 μm, 82 μm, 85 μm, 88 μm, 90 μm, 92 μm, 95 μm, 98 μm, or 100 μm.

Further, a specific distance is reserved between the third conductive contacts 22c and the third pad sets 13c after the blue LEDs 100c are extended into the third clamping grooves 121c, to ensure that the third conductive contacts 22c are not in contact with the third pad sets 13c, thereby preventing the third conductive contacts 22c from scratching the third pad sets 13c.
B29: Moving the third transfer base plate 20c in a preset direction X, to cause the blue LEDs 100c to be separated from the third transfer base plate 20c, as shown in FIG. 6I.

The anchoring force between the blue LEDs 100c and the third support cantilevers 21c is less than the mechanical strength of the barrier layer 12. Therefore, during the movement of the third transfer base plate 20c, the blue LEDs 100c are separated from the third support cantilevers 21c under the mechanical action of the barrier layer 12, thereby falling onto the third pad sets 13c in the third clamping grooves 121c. Transfer of the blue LEDs 100c under the action of mechanical force is achieved using the above transfer method. Therefore, the difficulty in transferring of the blue LEDs 100c is greatly reduced. In addition, no additional instrument or device is required during the transfer. Therefore, process costs can be greatly reduced.
B30: Soldering the first conductive contacts 22a to the first pad sets 13a, soldering the second conductive contacts 22b to the second pad sets 13b, and soldering the third conductive contacts 22c to the third pad sets 13c, as shown in FIG. 6J.

The first conductive contacts 22a, the second conductive contacts 22b, and the third conductive contacts 22c are melted in a manner of reflow soldering, so that the first conductive contacts 22a are bonded to the first pad sets 13a, the second conductive contacts 22b are bonded to the second pad sets 13b, and the third conductive contacts 22c are bonded to the third pad sets 13c, thereby completing the transfer of the LEDs 100.

Therefore, in the method for transferring LEDs provided in Example 2 of the present disclosure, the red LEDs 100a, the green LEDs 100b, and the blue LEDs 100c are transferred to the target base plate 10 in three times based on a direct transfer path of the LEDs. During transfer of the LEDs, when the LEDs are disposed in the corresponding clamping grooves, on the one hand, moving directions of the LEDs may be limited using the blocking effect of the barrier layer 12;

and on the other hand, because the mechanical strength of the barrier layer 12 is greater than the anchoring force between the LEDs and the corresponding support cantilevers when the transfer base plate is moved in a direction parallel to a plane in which the target substrate 11 is located, the LEDs can be easily separated from the transfer base plate, to complete the transfer of the LEDs. Further, the method for transferring LEDs provided in the present disclosure is performed under the action of a mechanical force. Therefore, the difficulty in transferring of the LEDs is greatly reduced. In addition, no additional instrument or device is required during the transfer. Therefore, process costs can be greatly reduced.

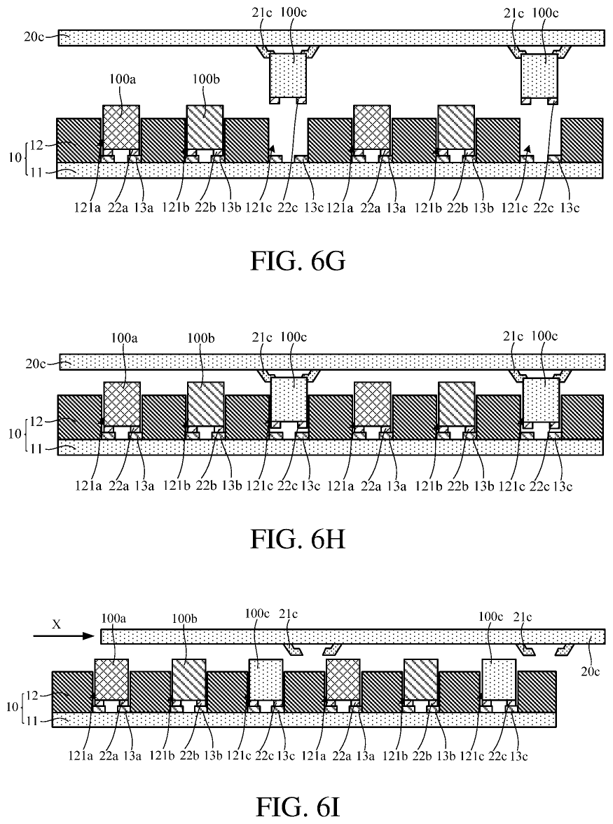

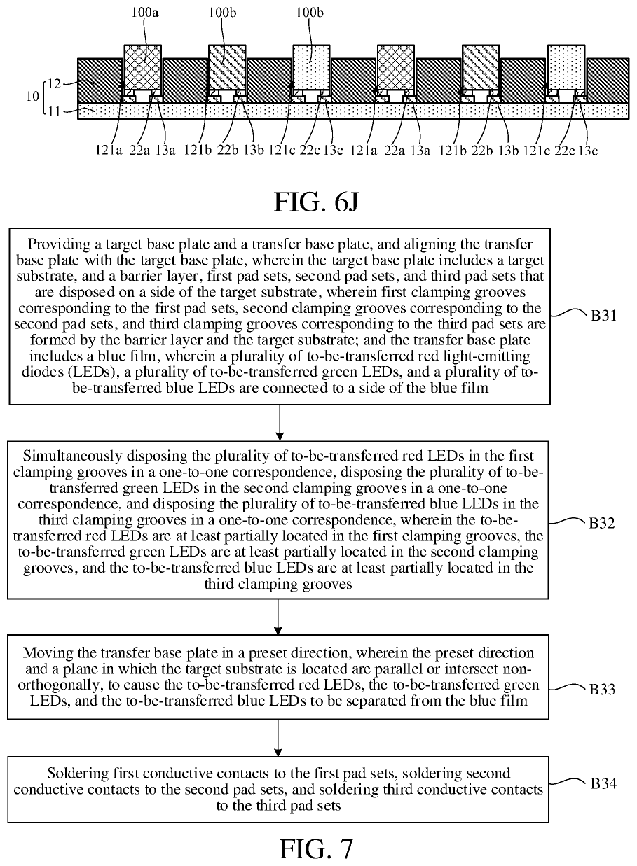

Referring to FIG. 7 and FIGS. 8A to 8D together, Example 3 of the present disclosure provides a method for transferring LEDs 100. The method includes steps of:
B31: Providing a target base plate 10 and a transfer base plate 20, and aligning the transfer base plate 20 with the target base plate 10, wherein the target base plate 10 includes a target substrate 11, and a barrier layer 12, first pad sets 13a, second pad sets 13b, and third pad sets 13c that are disposed on a side of the target substrate 11, wherein first clamping grooves 121a corresponding to the first pad sets 13a, second clamping grooves 121b corresponding to the second pad sets 13b, and third clamping grooves 121c corresponding to the third pad sets 13c are formed by the barrier layer 12 and the target substrate 11; and the transfer base plate 20 includes a blue film 20A, wherein a plurality of red LEDs 100a, a plurality of green LEDs 100b, and a plurality of blue LEDs 100c are connected to a side of the blue film 20A, as shown in FIG. 8A.

It should be noted that, in the present embodiment, the specific structure and related process for manufacturing the target base plate 10 are same as those in Example 2. Reference may be made to the descriptions of Example 2 for all the related technologies, so details are not described herein again.

In the present embodiment, the transfer base plate 20 further includes a transfer substrate 20B. The transfer substrate 20B is disposed on a side of the blue film 20A away from the LEDs 100. The transfer substrate 20B may be a sapphire substrate, a gallium arsenide substrate, a silicon-based substrate, or the like.

The red LEDs 100a, the green LEDs 100b, and the blue LEDs 100c may all be mini-LEDs or micro-LEDs.

First conductive contacts 22a are connected to sides of the red LEDs 100a away from the transfer base plate 20. The first conductive contacts 22a are configured to bind and bond to the first pad sets 13a on the target base plate 10. Second conductive contacts 22b are connected to sides of the green LEDs 100b away from the transfer base plate 20. The second conductive contacts 22b are configured to bind and bond to the second pad sets 13b on the target base plate 10. Third conductive contacts 22c are connected to sides of the blue LEDs 100c away from the transfer base plate 20. The third conductive contacts 22c are configured to bind and bond to the third pad sets 13c on the target base plate 10. The materials of the first conductive contacts 22a, the second conductive contacts 22b, and the third conductive contacts 22c are same, and may include one or more of metals having a low melting point such as tin, indium, lead, or bismuth.

In the present embodiment, the red LEDs 100a, the green LEDs 100b, and the blue LEDs 100c are all connected to the blue film 20A by the adhesion. The mechanical strength of the barrier layer 12 is greater than the adhesion between the red LEDs 100a, the green LEDs 100b, or the blue LEDs 100c and the blue film 20A.
B32: Simultaneously disposing the plurality of red LEDs 100a in the first clamping grooves 121a in a one-to-one correspondence, disposing the plurality of green LEDs 100b in the second clamping grooves 121b in a one-to-one correspondence, and disposing the plurality of blue LEDs 100c in the third clamping grooves 121c in a one-to-one correspondence, wherein the red LEDs 100a are at least partially located in the first clamping grooves 121a, the green LEDs 100b are at least partially located in the second clamping grooves 121b, and the blue LEDs 100c are at least partially located in the third clamping grooves 121c, as shown in FIG. 8B.

For the thickness of parts of the red LEDs 100a that are extended into the first clamping grooves 121a, the thickness of parts of the green LEDs 100b that are extended into the second clamping grooves 121b, and the thickness of parts of the blued LEDs 100c that are extended into the third clamping grooves 121c, reference may be made to the descriptions of Example 2, so details are not described herein again.
B33: Moving the transfer base plate 20 in a preset direction X, wherein the preset direction X and a plane in which the target substrate 11 is located are parallel or intersect non-orthogonally, to cause the red LEDs 100a, the green LEDs 100b, and the blue LEDs 100c to be separated from the blue film 20A, as shown in FIG. 8C.

The adhesion between the red LEDs 100a, the green LEDs 100b, or the blue LEDs 100c and the blue film 20A are less than the mechanical strength of the barrier layer 12. Therefore, in a transfer process of the transfer base plate 20, the red LEDs 100a, the green LEDs 100b, and the blue LEDs 100c are separated from the blue film 20A under the mechanical action of the barrier layer 12, thereby falling onto the corresponding pad sets. Because in the foregoing transfer method, the LEDs are transferred under the action of a mechanical force, the difficulty in transferring of the LEDs is greatly reduced. In addition, no additional instrument or device is required during the transfer. Therefore, process costs can be greatly reduced.
B34: Soldering the first conductive contacts 22a to the first pad sets 13a, soldering the second conductive contacts 22b to the second pad sets 13b, and soldering the third conductive contacts 22c to the third pad sets 13c, as shown in FIG. 8D.

The first conductive contacts 22a, the second conductive contacts 22b, and the third conductive contacts 22c are melted in a manner of reflow soldering, so that the first conductive contacts 22a are bonded to the first pad sets 13a, the second conductive contacts 22b are bonded to the second pad sets 13b, and the third conductive contacts 22c are bonded to the third pad sets 13c, thereby completing the transfer of the LEDs.

Therefore, in the method for transferring LEDs provided in Example 3 of the present disclosure, the transfer base plate 20 is used as a carrier base plate, and the red LEDs 100a, the green LEDs 100b, and the blue LEDs 100c are transferred to the target base plate 10 at a time based on an indirect transfer path of the LEDs. During transfer of the LEDs, when the LEDs are disposed in the corresponding clamping grooves, on the one hand, moving directions of the LEDs may be limited using the blocking effect of the barrier layer 12; and On the other hand, because the mechanical strength of the barrier layer 12 is greater than the adhesion between the LEDs and the blue film 20A, when the transfer base plate 20 is moved in a direction parallel to a plane in which the target substrate 11 is located, the LEDs can be easily separated from the transfer base plate 20, to complete the transfer of the LEDs. Further, the method for transferring LEDs provided in the present disclosure is performed under the action of a mechanical force. Therefore, the difficulty in transferring of the LEDs is greatly reduced, and the transfer yield is greatly improved. In addition, no additional instrument or device is required during the transfer. Therefore, process costs can be greatly reduced.

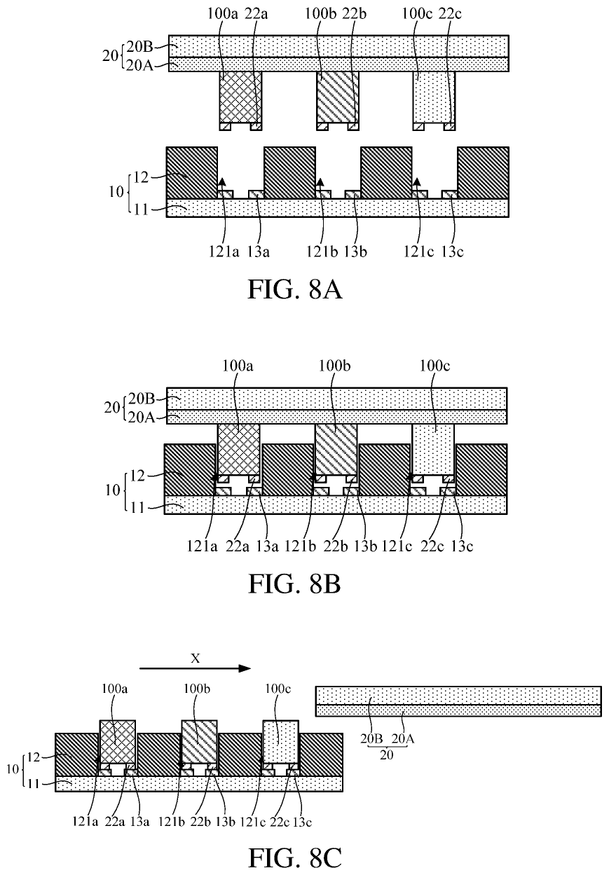

Referring to FIG. 9, an embodiment of the present disclosure further provides a light-emitting base plate 200. The light-emitting base plate 200 includes a target base plate 10 and a plurality of LEDs 100. The target base plate 10 includes a target substrate 11, and a barrier layer 12 and a plurality of pad sets 13 that are disposed on a side of the target substrate 11. A plurality of clamping grooves 121 are formed by the barrier layer 12 and the target substrate 11. One of the pad sets 13 is exposed from one of clamping grooves 121. The thickness of the pad sets 13 is less than the depth of the clamping grooves 121. One of the LEDs 100 is correspondingly disposed in one of the clamping grooves 121 and is connected to the pad set 13.

In a detailed description, the pad sets 13 include first pad sets 13a, second pad sets 13b, and third pad sets 13c. The clamping grooves 121 include first clamping grooves 121a, second clamping grooves 121b, and third clamping grooves 121c. One of the first pad sets 13a is exposed from one of the first clamping grooves 121a. The thickness of the first pad sets 13a is less than the depth of the first clamping grooves 121a. One of the second pad sets 13b is exposed from one of the second clamping grooves 121b. The thickness of the second pad sets 13b is less than the depth of the second clamping grooves 121b. One of the third clamping grooves 121c is exposed from one of the third pad sets 13c. The thickness of the third pad sets 13c is less than the depth of the third clamping grooves 121c.

The LEDs 100 include red LEDs 100a, green LEDs 100b, and blue LEDs 100c. The red LEDs 100a are located in the first clamping grooves 121a and are connected to the first pad sets 13a by the first conductive contacts 22a. The green LEDs 100b are located in the second clamping grooves 121b and are connected to the second pad sets 13b by the second conductive contacts 22b. The blue LEDs 100c are located in the third clamping grooves 121c and are connected to the third pad sets 13c by the third conductive contacts 22c.

In the present embodiment, a distance between a surface of each of the LEDs 100 away from the target substrate 11 and the target substrate 11 is greater than a distance between a surface of the barrier layer 12 away from the target substrate 11 and the target substrate 11.

The LEDs 100 may be obtained using the method for transferring LEDs 100 described in Example 1 or Example 2. For the related transfer method, reference may be made to the descriptions of Example 1 or Example 2, so details are not described herein again.

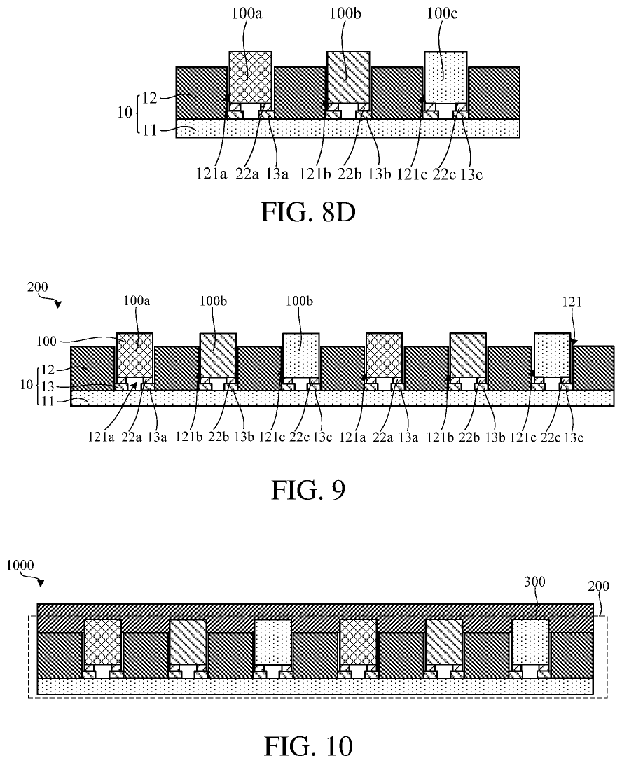

Referring to FIG. 10, an embodiment of the present disclosure further provides a display panel 1000. The display panel 1000 includes a light-emitting base plate 200 and a packaging layer 300 disposed on a side of the light-emitting base plate 200. The light-emitting base plate 200 may be the light-emitting base plate 200 described in the above embodiments. For a detailed structure of the light-emitting base plate 200, reference may be made to the descriptions of the foregoing embodiments, so details are not described herein again.

A method for transferring LEDs and a light-emitting base plate provided in the embodiments of the present disclosure are described in detail above. The principles and implementations of the present disclosure are described through specific examples in this specification. The descriptions of the embodiments are merely intended to help understand the methods and core ideas of the present disclosure. In addition, a person skilled in the art may make modifications to the specific implementations and application scopes according to the idea of the present disclosure. In conclusion, the content of this specification should not be construed as a limitation to the present disclosure.

What is claimed is:

1. A method for transferring light-emitting diodes (LEDs), comprising following steps of:
providing a target base plate and a transfer base plate, wherein the target base plate comprises a target substrate and a barrier layer disposed on a side of the target substrate, wherein a plurality of clamping grooves are formed by the barrier layer and the target substrate; and a plurality of LEDs are connected to a side of the transfer base plate;
aligning the target base plate with the transfer base plate, to cause the LEDs to be at least partially located in the clamping grooves; and
moving the transfer base plate in a preset direction, wherein the preset direction and a plane in which the target substrate is located are parallel or intersect non-orthogonally, to cause the LEDs to be separated from the transfer base plate.

2. The method for transferring LEDs as claimed in claim 1, wherein the mechanical strength of the barrier layer is greater than the bonding strength between the LEDs and the transfer base plate.

3. The method for transferring LEDs as claimed in claim 1, wherein in the step of aligning the target base plate with the transfer base plate, the LEDs are located in the clamping grooves by at least half the thickness of the LEDs in a direction perpendicular to the plane in which the target substrate is located.

4. The method for transferring LEDs as claimed in claim 3, wherein a distance between a surface of the barrier layer away from the target substrate and the target substrate ranges from 50 μm to 70 μm, and a distance between a surface of each of the LEDs away from the target substrate and the target substrate ranges from 80 μm to 100 μm.

5. The method for transferring LEDs as claimed in claim 2, wherein the transfer base plate is a growth substrate, support cantilevers are connected between the growth substrate and the LEDs, and the mechanical strength of the barrier layer is greater than an anchoring force between the LEDs and the support cantilevers; and
in the step of moving the transfer base plate in a preset direction, the LEDs are separated from the support cantilevers.

6. The method for transferring LEDs as claimed in claim 2, wherein the transfer base plate comprises a blue film connected to the plurality of LEDs, wherein the mechanical strength of the barrier layer is greater than the adhesion between the LEDs and the blue film; and
in the step of moving the transfer base plate in a preset direction, the LEDs are separated from the blue film.

7. The method for transferring LEDs as claimed in claim 1, wherein the barrier layer is formed using an inkjet printing process, and the material of the barrier layer comprises a polymer.

8. The method for transferring LEDs as claimed in claim 7, wherein the polymer comprises polyimide, epoxy resin, or acrylic resin.

9. The method for transferring LEDs as claimed in claim 1, wherein the material of the barrier layer comprises a light-shielding material.

10. The method for transferring LEDs as claimed in claim 1, wherein the target base plate further comprises a plurality of pad sets disposed on the side of the target substrate, one of the pad sets is exposed from one of the clamping grooves, the thickness of the pad sets is less than the depth of the clamping grooves, conductive contacts are connected to sides of the LEDs away from the transfer base plate, and after the step of moving the transfer base plate in a preset direction, the method further comprises:
soldering the conductive contacts to the corresponding pad sets.

11. The method for transferring LEDs as claimed in claim 1, wherein the LEDs are mini-LEDs or micro-LEDs.

12. A method for transferring light-emitting diodes (LEDs), comprising following steps of:
providing a target base plate and a transfer base plate, wherein the target base plate comprises a target substrate and a barrier layer disposed on a side of the target substrate, wherein a plurality of clamping grooves are formed by the barrier layer and the target substrate; and a plurality of LEDs are connected to a side of the transfer base plate, the mechanical strength of the barrier layer is greater than the bonding strength between the LEDs and the transfer base plate, and the material of the barrier layer comprises a polymer;
aligning the target base plate with the transfer base plate, to cause the LEDs to be at least partially located in the clamping grooves; and
moving the transfer base plate in a preset direction, wherein the preset direction and a plane in which the target substrate is located are parallel or intersect non-orthogonally, to cause the LEDs to be separated from the transfer base plate.

13. The method for transferring LEDs as claimed in claim 12, wherein in the step of aligning the target base plate with the transfer base plate, the LEDs are located in the clamping grooves by at least half the thickness of the LEDs in a direction perpendicular to the plane in which the target substrate is located.

14. The method for transferring LEDs as claimed in claim 13, wherein a distance between a surface of the barrier layer away from the target substrate and the target substrate ranges from 50 μm to 70 μm, and a distance between a surface of each of the LEDs away from the target substrate and the target substrate ranges from 80 μm to 100 μm.

15. The method for transferring LEDs as claimed in claim 12, wherein the transfer base plate is a growth substrate, support cantilevers are connected between the growth substrate and the LEDs, and the mechanical strength of the barrier layer is greater than an anchoring force between the LEDs and the support cantilevers; and
in the step of moving the transfer base plate in a preset direction, the LEDs are separated from the support cantilevers.

16. The method for transferring LEDs as claimed in claim 12, wherein the transfer base plate comprises a blue film connected to the plurality of LEDs, wherein the mechanical strength of the barrier layer is greater than the adhesion between the LEDs and the blue film; and
in the step of moving the transfer base plate in a preset direction, the LEDs are separated from the blue film.

17. The method for transferring LEDs as claimed in claim 12, wherein the barrier layer is formed using an inkjet printing process.

18. The method for transferring LEDs as claimed in claim 12, wherein the material of the barrier layer comprises a light-shielding material.

19. The method for transferring LEDs as claimed in claim 12, wherein the target base plate further comprises a plurality of pad sets disposed on the side of the target substrate, one of the pad sets is exposed from one of the clamping grooves, the thickness of the pad sets is less than the depth of the clamping grooves, conductive contacts are connected to sides of the LEDs away from the transfer base plate, and after the step of moving the transfer base plate in a preset direction, the method further comprises a following step:
soldering the conductive contacts to the corresponding pad sets.

20. A light-emitting base plate, comprising:
a target base plate, wherein the target base plate comprises a target substrate, and a barrier layer and a plurality of pad sets that are disposed on a side of the target substrate, wherein a plurality of clamping grooves are formed by the barrier layer and the target substrate, and one of the pad sets is exposed from one of the clamping grooves, and the thickness of the pad sets is less than the depth of the clamping grooves; and
a plurality of light-emitting diodes (LEDs), wherein one of the LEDs is correspondingly disposed in one of the clamping grooves and is connected to the pad set, wherein a distance between a surface of each of the LEDs away from the target substrate and the target substrate is greater than a distance between a surface of the barrier layer away from the target substrate and the target substrate.
